(19) United States
(12) Patent Application Publication
(10) Pub. No.: US 2010/0118449 A1
(43) Pub. Date: May 13, 2010

(54) NULLING CURRENT TRANSFORMER

(75) Inventors: Jonathan Keith Jackson, Argyll (GB); Andrew Williams, Conway (GB)

Correspondence Address: MCKEE, VOORHEES & SEASE, P.L.C., 801 GRAND AVENUE, SUITE 3200, DES MOINES, IA, 50309-2721, US

(73) Assignee: DEEPSTREAM TECHNOLOGIES LTD, BANGOR, GWYNEED (UK)

(21) Appl. No.: 12/529,634

(22) PCT Filed: Feb. 29, 2008
(86) PCT No.: PCT/GB2008/000711

§ 371 Date: Sep. 2, 2009

(30) Foreign Application Priority Data
Mar. 2, 2007 (GB) GB 0704038.9

(51) Int. Cl. H02H 3/00; H01F 38/28; G01R 31/06

(52) U.S. Cl. 361/42; 323/357; 324/547

(57) ABSTRACT

This invention relates to a nulling current transformer. More particularly, this invention relates to a nulling current transformer for accurately detecting current and giving an improved response, accuracy and stability using toroidal current transformer technology along with active components. This invention finds particular application in switchgear devices such as residual current devices and metering operations. The nulling current transformer is implemented in a closed magnetic core having at least one primary winding inductively coupled thereto. A secondary winding is also inductively coupled to said magnetic core, the secondary winding being responsive to any magnetic flux generated in said magnetic core. A separate tertiary winding is also inductively coupled to said magnetic core, the tertiary winding being responsive to any magnetic flux generated in the magnetic core. A nulling means is also provided for receiving the output of said tertiary winding and nulling the received output, the nulled output of the nulling means being connected to the input of said secondary winding such that it serves to cancel the magnetic flux in the magnetic core.

This invention relates to a nulling current transformer. More particularly, this invention relates to a nulling current transformer for accurately detecting current and giving an improved response, accuracy and stability using toroidal current transformer technology along with active components. This invention finds particular application in switchgear devices and metering operations.

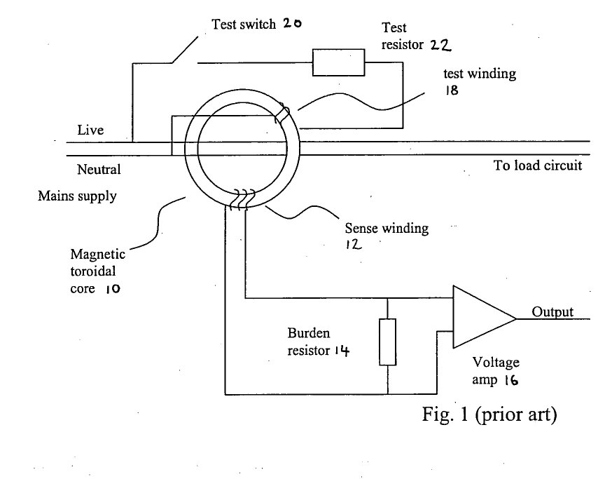

Circuit protection devices, such as residual current devices are routinely used to monitor and protect against electrocution and fire risks on electrical installations. The usual technique for obtaining and processing a residual fault current is shown in FIG. 1. The principle of operation of these devices is well known, and a toroidal current transformer is used to measure the sum of the live and neutral currents. The current transformer detects the magnetic fields of the two supply conductors which flow in opposite directions and cancel in normal circumstances. The supply conductors form single primary turns on a magnetic toroidal core 10 and a secondary sense winding 12 of many turns is used to detect any magnetisation of the toroidal core 10.

A typical fault may occur where a person touches the live conductor downstream of the residual current device allowing extra current to flow through live to ground, through the person. This current induces a fault current in the sense winding 12 which is converted to a voltage across a burden resistor 14 and this voltage is amplified 16 and fed to some further circuitry (not shown) which makes a decision as to whether the device will trip. If the outcome of this step is that a dangerous fault condition exists, then a signal can be used to energise a tripping mechanism (not shown), isolating the electrical supply.

As most residual current devices are electromechanical devices, they should be periodically tested, usually via a test button or switch 20 on the front of the device, to ensure reliable operation. As shown in FIG. 1, a test current, which simulates a fault current, is produced when the test button 20 is pressed. This is done by connecting a resistance 22 across the supply conductors, and when the test button 20 is pressed a current flows in a test winding 18 wound on the same toroidal core 10. A fault current is then induced in the secondary winding 12 which will trip the device.

The magnetic detection circuit, which includes magnetic toroidal core 10 and the secondary sense winding 12, has a low frequency cut-off and so the current transformer and burden resistor 14 values must be designed so as to ensure little filter action at the frequency of interest (50 Hz or 60 Hz). This requires a high inductance and low burden resistance, hence a large expensive inductor core 10 and large amplification gains.

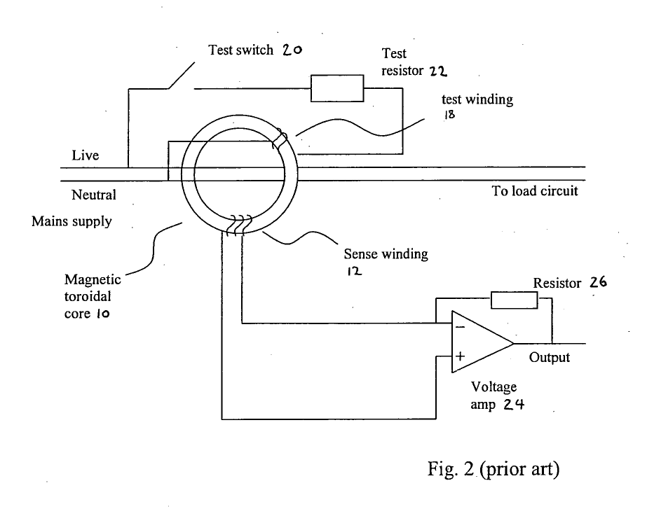

An alternative to FIG. 1 is to use a transresistance amplifier to convert the induced current directly to voltage, as shown in FIG. 2. This arrangement uses a voltage amplifier 24 with feedback resistor 26 arranged such that the output voltage is proportional to the input current and the input impedance is very low. This lessens the apparent burden resistance on the sense coil 12, improving performance with regard to low frequency cut-off which can easily drop to 1 Hz dependent upon the toroidal core 10 used.

The low frequency cut-off point of the magnetic detection circuit is important to performance in many ways. It is of course important that at the working frequency (50 Hz or 60 Hz) the response is on a level plateau some way above the cut-off knee. It should also be noted that as the cut-off frequency drops the amount of magnetic field in the core 10 decreases. This is explained by transformer approaching “ideal” performance where the primary and secondary currents produce fields which exactly cancel. The device will then become less dependent of variations in the magnetic properties of the core 10 material such as saturation, permanent magnetisation and variations in permeability due to temperature and ageing.

The properties of the magnetic detection circuit are of course not ideal which will affect performance. That is, the input is a current (the residual) and the output is also a current whose amplitude follows the input amplitude scaled by some linear factor. However, for several reasons the system is not ideally linear. These reasons are as follows:

(i) Frequency response. The system is AC coupled (as are all transformers) and so rely on varying AC magnetic fields to induce signals into the sense winding 12. This means at low frequencies the output signal amplitude will be lower than the anticipated ideal. The output drops to zero at DC. The cut-off frequency is determined by two factors, the sense winding 12 resistance and primary inductance. The size of the combined burden resistance 14 and winding resistance must be as low as possible (ideally zero ohms). The cut-off frequency increases as this resistance increases. The primary inductance is a function of the primary turns (usually just one in an residual current device), the magnetic permeability of the core 10 material and the core 10 dimensions. To achieve good response at low mains frequencies, the core 10 needs to be made of very high permeability material (10,000 to 100,000 times greater than free space) and the radius of the core 10 small but with the maximum possible cross-section of the material. Typically, a low frequency cut-off of 10 to 20 Hz is achievable such that at mains line frequencies (50 to 60 Hz) the response is reasonably flat.

(ii) Non-linear magnetic properties of the core 10. As the flux density in a magnetic material increases the permeability decreases and can decrease to a point where the output is distorted. It only takes a few milliamperes of residual current to saturate a core (i.e. permeability dropped to around that of free space). However, since 1 mA of primary produces 1 uA of secondary current in a 1000-turn sense winding 12 then both currents produce the same magnetic effect in the core material but in opposing directions. Hence, no magnetic field should be present in the core material (Lenz's Law). However, some magnetic field is always present as the output current always has an error making it smaller than expected so complete cancellation does not occur. The size of this error is frequency dependent (increasing as the frequency drops) but above the cut-off frequency can drastically reduce the magnetisation of the core material 10 thus limiting non-linear effects.

(iii) Remanent magnetisation. The core material can become magnetised by a large fault current being suddenly disconnected as breakers trip. If this happens the core material will demonstrate low permeability and may cause the current transformer output to be attenuated to an extent that the device fails to detect a fault on reconnection of the supply.

(iv) Drift. The permeability of the core 10 changes with temperature and time which can shift the cut-off frequency upwards and effect performance at mains frequencies.

Existing residual current devices suffer from all the above effects to some degree. The present invention aims to reduce these effects so as to significantly improve the performance of existing sensors or to allow the use of lower quality sensors to achieve similar performance. This is achieved by alteration of the magnetic detection circuit.

In the prior art, nulling using a Hall-effect sensor placed in a gap in the magnetic core has been proposed. However, the required air gap seriously compromises the core performance, especially with regard to summing two opposite currents accurately as occurs in RCD devices. Active transformers have been described, but usually require a second core alongside the magnetic core 10 to produce a nulling field.

It is the object of the present invention to provide a nulling current transformer for accurately detecting current and giving an improved response, accuracy and stability using toroidal current transformer technology along with active components.

According to the present invention there is provided a nulling current transformer having a closed magnetic core and at least one primary winding inductively coupled thereto, comprising:

a secondary winding inductively coupled to said magnetic core, said secondary winding being responsive to any magnetic flux generated in said magnetic core;

a tertiary winding inductively coupled to said magnetic core, said tertiary winding being responsive to any magnetic flux generated in said magnetic core; and

nulling means for receiving the output of said tertiary winding and nulling the received output, the nulled output of said nulling means being connected to the input of said secondary winding such that it serves to cancel the magnetic flux in said magnetic core.

Likewise according to the present invention there is provided a method of nulling a current transformer having a closed magnetic core and at least one primary winding inductively coupled thereto, comprising:

monitoring the output of a secondary winding inductively coupled to said magnetic core, said secondary winding being responsive to any magnetic flux generated in said magnetic core;

monitoring the output of a tertiary winding inductively coupled to said magnetic core, said tertiary winding being responsive to any magnetic flux generated in said magnetic core; and

receiving the output of said tertiary winding and nulling the received output, the nulled output being connected to the input of said secondary winding such that it serves to cancel the magnetic flux in said magnetic core.

Preferably, the nulling current transformer may be incorporated as part of a residual current device. In use, the output of the secondary winding is converted to a voltage across a burden resistor and this voltage is amplified and fed to a tripping processor.

In one embodiment, the tertiary winding may be a test coil which is used to test the device. In use, the nulling means comprises a first stage amplifier which boosts the voltage from said tertiary winding, and which causes a current to flow in the secondary winding. Preferably, the signs of the signals are arranged such that the voltage induced in tertiary winding from the secondary winding opposes the voltage produced by the primary winding. This essentially produces negative feedback to keep the tertiary winding voltage near zero and nulls the flux in the magnetic core.

In use, the tertiary winding may be used in voltage mode to detect any flux present in the core but since no current flows in this winding it does not change the flux. This signal is used to create a current to cancel the flux to produce a result of near zero. The cancellation is ensured using a closed feedback loop which includes the magnetic core. Preferably, the current used to null the field will be exactly related to primary fault current by a ratio determined by the windings.

As both amplifiers are DC coupled and of high gain then offset voltages inherent in the amplifiers would produce large DC voltages on the amplifier outputs which wastes power and can saturate the magnetic core. In use, in order to overcome this, very low offset amplifiers may be used or a feedback system is used to produce an offset voltage to null the offset produced by the amplifiers.

Further according to the present invention there is provided a residual current device having a trip mechanism for isolating an electric supply to an electrical installation upon detection of a predetermined current imbalance between the line and neutral conductors of said electric supply, comprising:

a current transformer having a closed magnetic core and having the line and neutral conductors inductively coupled as a primary winding;

a secondary winding inductively coupled to said magnetic core and connectable to said trip mechanism, said secondary winding being responsive to said current imbalance on said electrical installation;

a tertiary winding inductively coupled to said magnetic core and responsive to said current imbalance on said electrical installation; and

nulling means for receiving the output of said tertiary winding and nulling the received output, the nulled output of said nulling means being connected to the input of said secondary winding such that it serves to demagnetise said magnetic core.

It is believed that a nulling current transformer in accordance with the present invention at least addresses the problems outlined above. The advantages of the present invention are that a nulling current transformer for accurately detecting current is provided that gives an improved response, accuracy and stability using toroidal current transformer technology along with active components.

A specific non-limiting embodiment of the invention will now be described by way of example and with reference to the accompanying drawings, in which:

FIG. 1 shows schematically the operation of a known residual current device which includes a test facility to simulate a fault condition;

FIG. 2 illustrates an alternative prior art residual current device; and

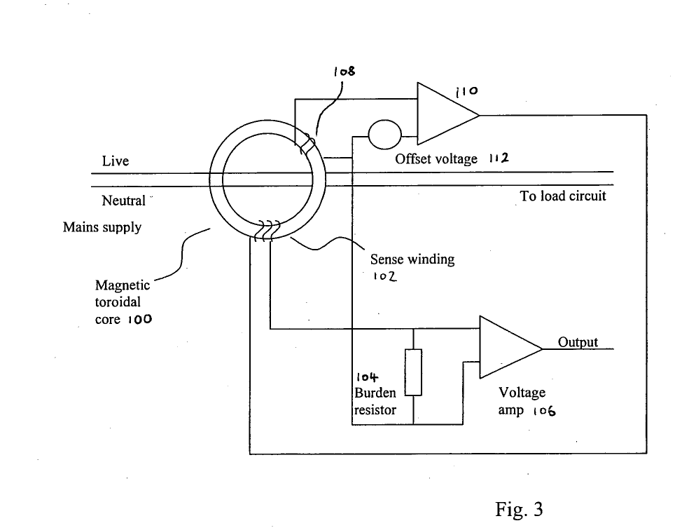

FIG. 3 shows schematically how the present invention can be implemented as a switchgear device.

Referring now to the drawings, a nulling current transformer according to the present invention is shown schematically in FIG. 3. FIG. 3 shows an embodiment where the nulling current transformer is incorporated as part of a residual current device. As shown in FIG. 3, the phase and neutral cables from the supply to the load pass through a magnetic toroid 100. On the toroid 100 is wound a sense coil 102; the toroid 100 and sense coil 102 arrangement being referred to as a current transformer. Under normal conditions, the phase and neutral currents are equal and opposite, and no flux is induced in the toroid 100 and hence no current flows in the sense coil 102. If a fault condition occurs, and current flows through the earth path back to the electrical supply, the phase and neutral currents will no longer be balanced and flux will be induced in the toroid 100, and a sense current will flow in the sense coil 102. The sense current generates a voltage across a burden resistor 104 and this voltage is amplified using amplifier 106. The output of amplifier 106 is connected to some further circuitry (not shown), which makes a trip decision and, if appropriate, open contacts in the electrical supply (not shown).

For the reasons previously described above, non-linearities in the magnetic detection circuit and any remanent magnetisation of the toroid 100 can seriously affect the performance and sensitivity of the current transformer, and the present invention takes the concept of cancelling the magnetic flux in the toroidal core 100 further.

FIG. 3 shows that a separate tertiary winding 108 is wound on the toroid 100. In one embodiment, it is envisaged that the tertiary winding 108 could be the test coil which is used to test the device. The output of the tertiary winding 108 is taken to a first stage amplifier 110 which boosts the voltage from this coil 108, and which causes a current to flow in the sense winding 102. The signs of the signals are arranged such that the voltage induced in tertiary winding 108 from the sense winding 102 opposes the voltage produced by the primary. This essentially produces negative feedback to keep the tertiary winding voltage near zero thus nulling the field in the core 100. The current in the sense winding 102 is amplified as previously described to produce an output for tripping decisions.

The tertiary winding 108 is used in voltage mode to detect any flux present in the core 100 but since no current flows in this winding 108 it does not change the flux. This signal is used to create a current to cancel the flux to produce a result of near zero. The cancellation is ensured using a closed feedback loop which includes the magnetic core 100. The current used to null the field will be exactly related to primary fault current by a ratio determined by the windings. This nulling current can then be converted into a voltage using the techniques described previously (i.e., burden resistor or transresistance amplifier).

The effect of the feedback loop can be shown using equivalent circuit analysis to greatly reduce the sense winding burden making the frequency cut-off very low (10 mH). This gives the system excellent accuracy, stability and insensitivity to magnetic non-linearities of the core material.

It is noted in FIG. 3 that an offset voltage is required. Since both amplifiers 106, 110 are DC coupled and of high gain then offset voltages inherent in the amplifiers 106, 110 would produce large DC voltages on the amplifier outputs which wastes power and can saturate the magnetic core 100. To overcome this either very low offset amplifiers are used or a feedback system is used to produce an offset voltage to null the offset produced by the amplifiers 106, 110.

Various alterations and modifications may be made to the present invention without departing from the scope of the invention. For example, although particular embodiments refer to implementing the present invention on a single phase electrical installation, this is in no way intended to be limiting as, in use, the present invention can be incorporated into larger installations, both single and multi-phase.

The circuit described in FIG. 3 is related to an RCD switchgear device where two or more currents are summed within the current transformer and the residual is measured. The measured residual is usually zero or small in such applications. However, this technique also has merit in applications such as metering where a single conductor passes through the current transformer and the actual load current is measured. Such currents are much larger and can quickly saturate the core unless a physically large core is used. The nulling technique described greatly increases the current required to cause saturation such that the use of smaller, cheaper cores become possible.

1. A nulling current transformer having a closed magnetic core and at least one primary winding inductively coupled thereto, comprising:
a secondary winding inductively coupled to said magnetic core, said secondary winding being responsive to any magnetic flux generated in said magnetic core;
a tertiary winding inductively coupled to said magnetic core, said tertiary winding being responsive to any magnetic flux generated in said magnetic core; and
nulling means for receiving the output of said tertiary winding and nulling the received output, the nulled output of said nulling means being connected to the input of said secondary winding such that it serves to cancel the magnetic flux in said magnetic core.

2. The nulling current transformer as claimed in claim 1, wherein the nulling current transformer is incorporated as part of a residual current device.

3. The nulling current transformer as claimed in claim 1, wherein the output of the secondary winding is converted to a voltage across a burden resistor and this voltage is amplified and fed to a tripping processor.

4. The nulling current transformer as claimed in claim 1, wherein the tertiary winding is also a test coil which is used to test the device.

5. The nulling current transformer as claimed in claim 1, wherein the nulling means comprises a first stage amplifier which boosts the voltage from said tertiary winding and causes a current to flow in said secondary winding.

6. The nulling current transformer as claimed in claim 5, wherein said first stage amplifier is configured such that voltage induced in tertiary winding from the secondary winding opposes the voltage produced by the primary winding.

7. The nulling current transformer as claimed in claim 5, wherein said first stage amplifier produces negative feedback to keep the tertiary winding voltage near zero which nulls the flux in the magnetic core.

8. A nulling current transformer as claimed in claim 5, wherein said first stage amplifier is a very low offset amplifier or a feedback system is used to produce an offset voltage to null any offset produced by the amplifier.

9. The nulling current transformer as claimed in claim 1, wherein the tertiary winding is used in voltage mode to detect any flux present in the core and, as no current flows in this winding, it does not change the flux.

10. The nulling current transformer as claimed in claim 9, further comprising a closed feedback loop which includes the magnetic core.

11. The nulling current transformer as claimed in claim 9, wherein the current used to null the field will be exactly related to primary fault current by a ratio determined by the windings.

12. A method of nulling a current transformer having a closed magnetic core and at least one primary winding inductively coupled thereto, comprising:
monitoring the output of a secondary winding inductively coupled to said magnetic core, said secondary winding being responsive to any magnetic flux generated in said magnetic core;
monitoring the output of a tertiary winding inductively coupled to said magnetic core, said tertiary winding being responsive to any magnetic flux generated in said magnetic core; and
receiving the output of said tertiary winding and nulling the received output, the nulled output being connected to the input of said secondary winding such that it serves to cancel the magnetic flux in said magnetic core.

13. The method of nulling a current transformer as claimed in claim 12, wherein the nulling current transformer is incorporated as part of a residual current device.

14. The method of nulling a current transformer as claimed in claim 12, wherein the output of the secondary winding is converted to a voltage across a burden resistor and this voltage is amplified and fed to a tripping processor.

15. The method of nulling a current transformer as claimed in claim 12, wherein the tertiary winding is also a test coil which is used to test the device.

16. The method of nulling a current transformer as claimed in claim 12, wherein the step of receiving the output of said tertiary winding and nulling the received output further comprises boosting the voltage from said tertiary winding using a first stage amplifier and causing a current to flow in said secondary winding.

17. The method of nulling a current transformer as claimed in claim 16, wherein said first stage amplifier is configured such that voltage induced in tertiary winding from the secondary winding opposes the voltage produced by the primary winding.

18. The method of nulling a current transformer as claimed in claim 16, wherein said first stage amplifier produces negative feedback to keep the tertiary winding voltage near zero which nulls the flux in the magnetic core.

19. The method of nulling a current transformer as claimed in claim 16, wherein said first stage amplifier is a very low offset amplifier or a feedback system is used to produce an offset voltage to null any offset produced by the amplifier.

20. The method of nulling a current transformer as claimed in claim 12, wherein the tertiary winding is used in voltage mode to detect any flux present in the core and, as no current flows in this winding, it does not change the flux.

21. The method of nulling a current transformer as claimed in claim 20, further comprising a closed feedback loop which includes the magnetic core.

22. The method of nulling a current transformer as claimed in claim 20, wherein the current used to null the field is exactly related to primary fault current by a ratio determined by the windings.

23. A residual current device having a trip mechanism for isolating an electric supply to an electrical installation upon detection of a predetermined current imbalance between the line and neutral conductors of said electric supply, comprising:
a current transformer having a closed magnetic core and having the line and neutral conductors inductively coupled as a primary winding;
a secondary winding inductively coupled to said magnetic core and connectable to said trip mechanism, said secondary winding being responsive to said current imbalance on said electrical installation;
a tertiary winding inductively coupled to said magnetic core and responsive to said current imbalance on said electrical installation; and
nulling means for receiving the output of said tertiary winding and nulling the received output, the nulled output of said nulling means being connected to the input of said secondary winding such that it serves to demagnetise said magnetic core.

24. A nulling current transformer as described herein with reference to FIG. 3 of the accompanying drawings.

25. A method of nulling a current transformer having a closed magnetic core and at least one primary winding inductively coupled thereto as hereinbefore described.

26. A residual current device as described herein with reference to FIG. 3 of the accompanying drawings.
